(19) United States
(12) Patent Application Publication
(10) Pub. No.: US 2024/0112728 A1
(43) Pub. Date: Apr. 4, 2024

(54) ANALOG IN-MEMORY COMPUTATION PROCESSING CIRCUIT USING SEGMENTED MEMORY ARCHITECTURE

(71) Applicant: STMicroelectronics International N.V., Geneva (CH)

(72) Inventors: Harsh RAWAT, Faridabad (IN); Kedar Janardan DHORI, Ghaziabad (IN); Dipti ARYA, Noida (IN); Promod KUMAR, Greater Noida (IN); Nitin CHAWLA, Noida (IN); Manuj AYODHYAWASI, Noida (IN)

(73) Assignee: STMicroelectronics International N.V., Geneva (CH)

(21) Appl. No.: 18/244,782

(22) Filed: Sep. 11, 2023

Related U.S. Application Data
(60) Provisional application No. 63/411,775, filed on Sep. 30, 2022.

(51) Int. Cl. G11C 11/418; G11C 11/412; G11C 11/419

(52) U.S. Cl. CPC G11C 11/418; G11C 11/412; G11C 11/419; H03M 1/12

(57) ABSTRACT

A memory array includes sub-arrays with memory cells arranged in a row-column matrix where each row includes a word line and each sub-array column includes a local bit line. A control circuit supports a first operating mode where only one word line in the memory array is actuated during memory access and a second operating mode where one word line per sub-array is simultaneously actuated during an in-memory computation performed as a function of weight data stored in the memory and applied feature data. Computation circuitry coupling each memory cell to the local bit line for each column of the sub-array logically combines a bit of feature data for the in-memory computation with a bit of weight data to generate a logical output on the local bit line which is charge shared with the global bit line.

### CROSS REFERENCE TO RELATED APPLICATIONS

This application claims priority to United States Provisional Application for Patent No. 63/411,775, filed Sep. 30, 2022, the disclosure of which is incorporated herein by reference.

### TECHNICAL FIELD

Embodiments herein relate to an analog in-memory computation processing circuit and, in particular, to the use of a segmented memory (for example, a static random access memory (SRAM)) architecture for analog in-memory computation.

### BACKGROUND

Reference is made to FIG. 1 which shows a schematic diagram of an analog in-memory computation circuit 10. The circuit 10 utilizes a memory circuit including an array 12 of the memory cells 14 (for example, a static random access memory (SRAM) array formed by standard 6T SRAM memory cells) arranged in a matrix format having N rows and M columns. As an alternative, a standard 8T memory cell or an SRAM or another type of bitcell with a similar functionality and topology could instead be used. Each memory cell 14 is programmed to store a bit of a computational weight or kernel data for an in-memory compute operation. In this context, the in-memory compute operation is understood to be a form of a high dimensional Matrix Vector Multiplication (MVM) supporting multi-bit weights that are stored in multiple bit cells of the memory. The group of bit cells (in the case of a multibit weight) can be considered as a virtual synaptic element. Each bit of the computational weight has either a logic “1” or a logic “0” value.

Each memory cell 14 includes a word line WL and a pair of complementary bit lines BLT and BLC. The 8T-type SRAM cell would additionally include a read word line RWL and a read bit line RBL. The cells 14 in a common row of the matrix are connected to each other through a common word line WL (and through the common read word line RWL in the 8T-type implementation). The cells 14 in a common column of the matrix are connected to each other through a common pair of complementary bit lines BLT and BLC (and through the common read bit line RBL in the 8T-type implementation). Each word line WL, RWL is driven by a word line driver circuit 16 which may be implemented as a CMOS driver circuit (for example, a series connected p-channel and n-channel MOSFET transistor pair forming a logic inverter circuit). The word line signals applied to the word lines, and driven by the word line driver circuits 16, are generated from feature data input to the in-memory computation circuit and controlled by a row controller circuit 18. A column processing circuit 20 senses the analog signals on the pairs of complementary bit lines BLT and BLC (and/or on the read bit line RBL) for the M columns, converts the analog signals to digital signals, performs digital calculations on the digital signals and generates a decision output for the in-memory compute operation.

Although not explicitly shown in FIG. 1, it will be understood that the circuit 10 further includes conventional row decode, column decode, and read-write circuits known to those skilled in the art for use in connection with writing bits of data (for example, the computational weight data) to, and reading bits of data from, the SRAM cells 14 of the memory array 12. This operation is referred to as a conventional memory access mode and is distinguished from the analog in-memory compute operation discussed above.

With reference now to FIG. 2, each memory cell 14 of the 6T type includes two cross-coupled CMOS inverters 22 and 24, each inverter including a series connected p-channel and n-channel MOSFET transistor pair. The inputs and outputs of the inverters 22 and 24 are coupled to form a latch circuit having a true data storage node QT and a complement data storage node QC which store complementary logic states of the stored data bit. The cell 14 further includes two transfer (passgate) transistors 26 and 28 whose gate terminals are driven by a word line WL. The source-drain path of transistor 26 is connected between the true data storage node QT and a node associated with a true bit line BLT. The source-drain path of transistor 28 is connected between the complement data storage node QC and a node associated with a complement bit line BLC. The source terminals of the p-channel transistors 30 and 32 in each inverter 22 and 24 are coupled to receive a high supply voltage (for example, Vdd) at a high supply node, while the source terminals of the n-channel transistors 34 and 36 in each inverter 22 and 24 are coupled to receive a low supply voltage (for example, ground (Gnd) reference) at a low supply node.

With reference now to FIG. 3, each memory cell 14 of the 8T type includes two cross-coupled CMOS inverters 22 and 24, each inverter including a series connected p-channel and n-channel MOSFET transistor pair. The inputs and outputs of the inverters 22 and 24 are coupled to form a latch circuit having a true data storage node QT and a complement data storage node QC which store complementary logic states of the stored data bit. The cell 14 further includes two transfer (passgate) transistors 26 and 28 whose gate terminals are driven by a word line WL. The source-drain path of transistor 26 is connected between the true data storage node QT and a node associated with a true bit line BLT. The source-drain path of transistor 28 is connected between the complement data storage node QC and a node associated with a complement bit line BLC. The source terminals of the p-channel transistors 30 and 32 in each inverter 22 and 24 are coupled to receive a high supply voltage (for example, Vdd) at a high supply node, while the source terminals of the n-channel transistors 34 and 36 in each inverter 22 and 24 are coupled to receive a low supply voltage (for example, ground (Gnd) reference) at a low supply node. A signal path between the read bit line RBL and the low supply voltage reference is formed by series coupled transistors 38 and 40. The gate terminal of the (read) transistor 38 is coupled to the complement storage node QC and the gate terminal of the (transfer) transistor 40 is coupled to receive the signal on the read word line RWL.

The word line driver circuits 16 are typically coupled to receive the high supply voltage (Vdd) at the high supply node and are referenced to the low supply voltage (Gnd) at the low supply node.

The row controller circuit 18 receives the feature data for the in-memory compute operation and in response thereto performs the function of selecting which ones of the word lines WL<0> to WL<N−1> (or read word lines RWL<0> to RWL<N−1>) are to be simultaneously accessed (or actuated) in parallel during an analog in-memory compute operation, and further functions to control application of pulsed signals to the word lines in accordance with that in-memory compute operation. FIG. 1 illustrates, by way of example only, the simultaneous actuation of all N word lines with the pulsed word line signals, it being understood that in-memory compute operations may instead utilize a simultaneous actuation of fewer than all rows of the SRAM array. The analog signals on a given pair of complementary bit lines BLT and BLC (or analog signal on the read bit line RBL in the 8T-type implementation) are dependent on the logic state of the bits of the computational weight stored in the memory cells 14 of the corresponding column and the width(s) of the pulsed word line signals applied to those memory cells 14.

The implementation illustrated in FIG. 1 shows an example in the form of a pulse width modulation (PWM) for the applied word line signals for the in-memory compute operation dependent on the received feature data. The use of PWM or period pulse modulation (PTM) for the applied word line signals is a common technique used for the in-memory compute operation based on the linearity of the vector for the multiply-accumulation (MAC) operation. The pulsed word line signal format can be further evolved as an encoded pulse train to manage block sparsity of the feature data of the in-memory compute operation. It is accordingly recognized that an arbitrary set of encoding schemes for the applied word line signals can be used when simultaneously driving multiple word lines. Furthermore, in a simpler implementation, it will be understood that all applied word line signals in the simultaneous actuation may instead have a same pulse width.

FIG. 4 is a timing diagram showing simultaneous application of the example pulse width modulated word line signals to plural rows of memory cells 14 in the SRAM array 12 for a given analog in-memory compute operation, and the development over time of voltages Va,T and Va,C on one corresponding pair of complementary bit lines BLT and BLC, respectively, or development over time of voltage Va,R on one read bit line RBL, in response to sinking of cell read current due to the pulse width(s) of those word line signals and the logic state of the bits of the computational weight stored in the memory cells 14. The representation of the voltage Va levels as shown is just an example. Within the time of the computation cycle of the analog in-memory compute operation, the analog-to-digital converter (ADC) circuit of the column processing circuit 20 will sample (at time ts) the voltage Va level for conversion to a digital signal which is then subjected to the required digital computations for generating the decision output. After completion of the computation cycle, the voltage Va levels return to the bit line precharge Vdd level.

### SUMMARY

In an embodiment, a circuit comprises: a memory array including memory cells arranged in a matrix with plural rows and plural columns, each row including a word line connected to the memory cells of the row, and each memory cell storing a bit of weight data for an in-memory computation operation; wherein the memory is divided into a plurality of sub-arrays of memory cells, each sub-array including at least one row of said plural rows and said plural columns; a local bit line for each column of the sub-array; and a plurality of global bit lines.

A word line drive circuit is provided for each row having an output connected to drive the word line of the row, and a row controller circuit is coupled to the word line drive circuits and configured to simultaneously actuate one word line per sub-array during said in-memory computation operation.

Computation circuitry couples each memory cell in the column of the sub-array to the local bit line for each column of the sub-array, with the computation circuitry configured to logically combine a bit of feature data for the in-memory computation operation with the stored bit of weight data to generate a logical output on the local bit line. A plurality of local bit lines are coupled for charge sharing to each global bit line.

A column processing circuit senses analog signals on the global bit lines generated in response to said charge sharing, converts the analog signals to digital signals, performs digital signal processing calculations on the digital signals and generates a decision output for the in-memory computation operation.

In an implementation, each column of the memory array has an associated global bit line, and the plurality of local bit lines that are coupled for charge sharing with each global bit line comprise local bit lines in a corresponding column of the plurality of sub-arrays. Feature data is applied in a direction of the rows of the memory array.

In another implementation, each sub-array has an associated global bit line, and the plurality of local bit lines that are coupled for charge sharing with each global bit line comprise local bit lines in the sub-array. Feature data is applied in a direction of the columns of the memory array.

A charge sharing circuit is coupled between the plurality of local bit lines and each global bit line. In one implementation, the charge sharing circuit is a capacitance between each local bit line of said plurality of local bit lines and the global bit line. In another implementation, the charge sharing circuit comprises: a first capacitance of each local bit line of said plurality of local bit lines; a second capacitance of the global bit line; and a switch selectively connecting each first capacitance to the second capacitance.

### BRIEF DESCRIPTION OF THE DRAWINGS

For a better understanding of the embodiments, reference will now be made by way of example only to the accompanying figures in which:

FIG. 1 is a schematic diagram of an analog in-memory computation circuit;

FIG. 2 is a circuit diagram of a standard 6T static random access memory (SRAM) cell;

FIG. 3 is a circuit diagram of an 8T SRAM cell;

FIG. 4 is a timing diagram illustrating an analog in-memory compute operation;

FIG. 5 is a schematic diagram of a further embodiment of an analog in-memory computation circuit;

FIG. 6 is a timing diagram illustrating an analog in-memory compute operation;

FIG. 7 is a circuit diagram of an alternative embodiment for an SRAM cell;

FIGS. 8-10 are schematic diagrams of other embodiments for an analog in-memory computation circuit;

FIG. 11 is a diagram for a switch capacitor weighting circuit;

FIG. 12 is a circuit diagram of an alternative embodiment for an SRAM cell;

FIGS. 13-17 are schematic diagrams of further embodiments for an analog in-memory computation circuit; and

FIG. 18 is a circuit diagram of an alternative embodiment for an SRAM cell;

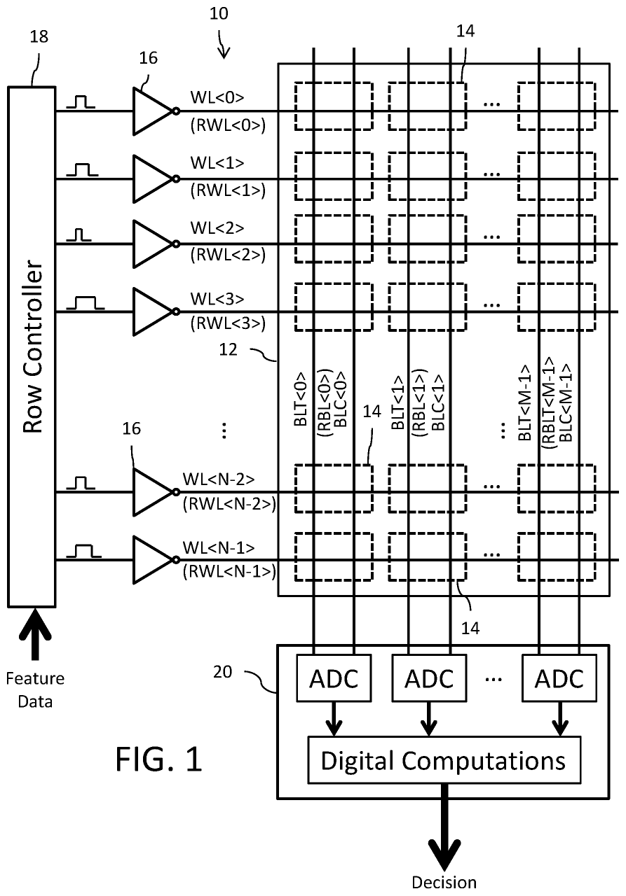

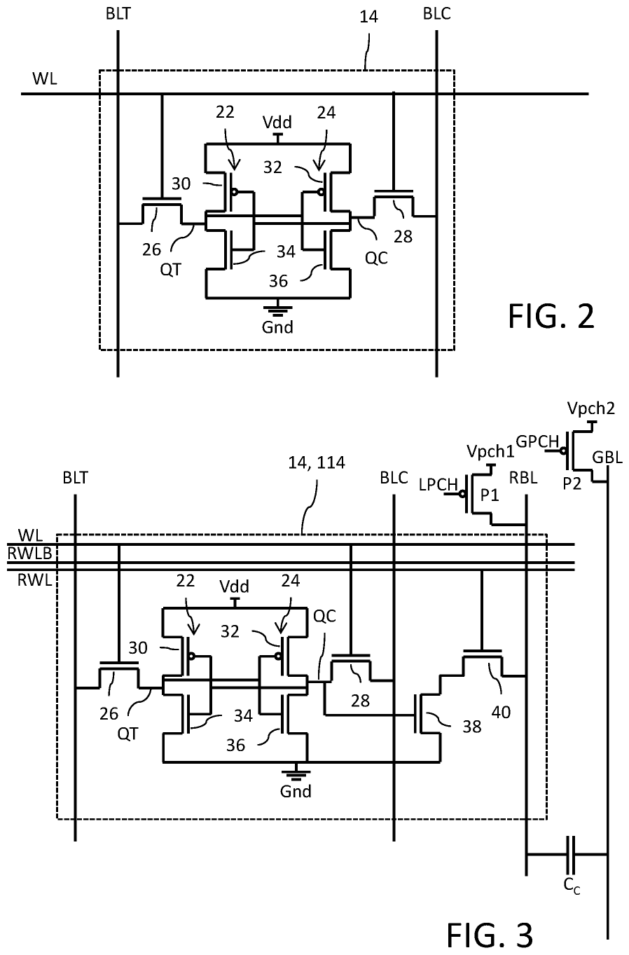

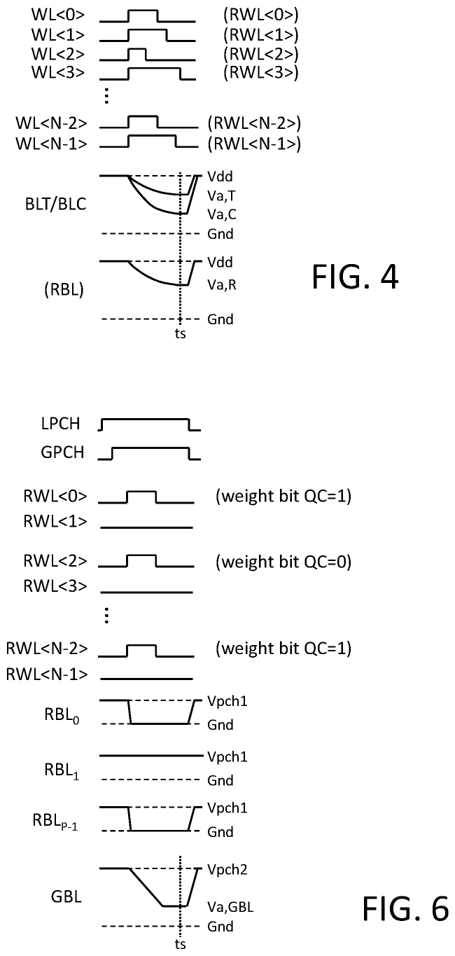

### DETAILED DESCRIPTION OF THE DRAWINGS

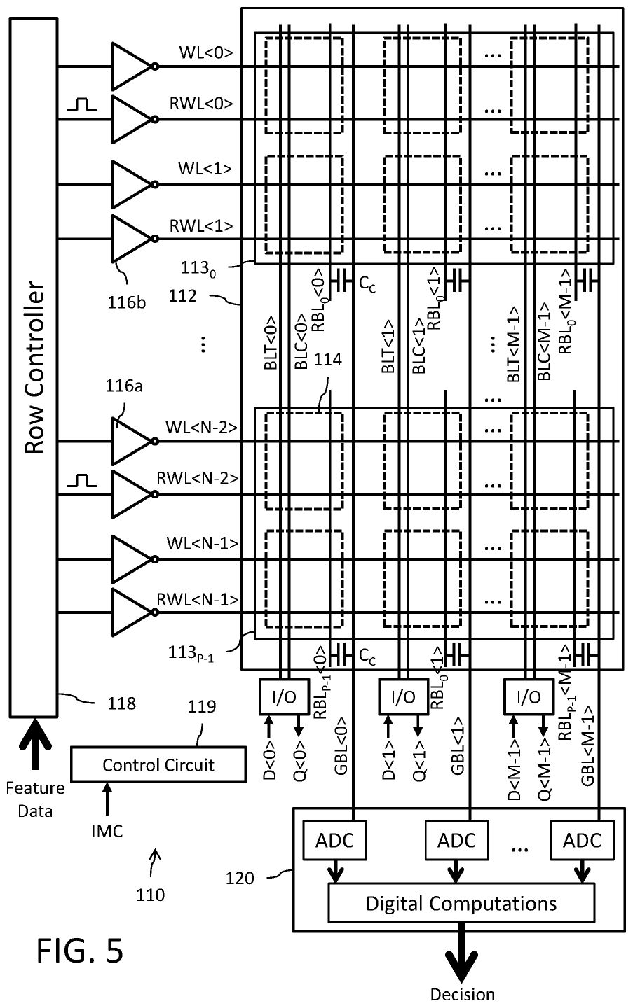

Reference is now made to FIG. 5 which shows a block diagram of an analog in-memory computation circuit 110. The circuit 110 is implemented using a memory circuit which includes a memory array 112 (for example, a static random access memory (SRAM) array) formed by a plurality of memory cells 114 arranged in a matrix format having N rows and M columns. Each memory cell 114 is programmed to store a bit of data. In conventional memory access processing, the stored data in the memory array 112 can be any desired user data. In analog in-memory computation processing, the stored data in the memory array 112 comprises computational weight or kernel data for an analog in-memory compute operation. In this context, the analog in-memory compute operation is understood to be a form of a high dimensional Matrix Vector Multiplication (MVM) supporting multi-bit weights that are stored in multiple bit cells of the memory. The group of bit cells (in the case of a multibit weight) can be considered as a virtual synaptic element. Each bit of data stored in the memory array, whether user data or weight data, has either a logic “1” or a logic “0” value.

In an embodiment, each memory cell 114 is based on the 8T-type SRAM cell (see, FIG. 3, for example) and includes a word line WL, a pair of complementary bit lines BLT and BLC, a read word line RWL and a read bit line RBL. The memory cells in a common row of the matrix are connected to each other through a common word line WL. Each of the word lines WL is driven by a word line driver circuit 116a with a word line signal generated by a row controller circuit 118 during conventional memory access (read and write) operations. The memory cells in a common column of the matrix across the whole array 112 are connected to each other through a common pair of complementary bit lines BLT and BLC which are coupled to a column input/output (I/O) circuit. For a conventional memory write operation, a single one of the word lines WL for the array 112 is asserted by the row controller circuit 118 with a word line signal, and the data received at the data input port D<0> to D<M−1> of the I/O circuits is written to the cells of the memory array 112 coupled to the asserted word line. For a conventional memory read operation, a single one of the word lines WL for the array 112 is asserted by the row controller circuit 118 with a word line signal, and the data stored in the cells of the memory array 112 coupled to the asserted word line is read out to the data output port Q<0> to Q<M−1> of the I/O circuits.

The memory cells in a common row of the matrix are further connected to each other through a common read word line RWL. Each of the read word lines RWL is driven by a word line driver circuit 116b with a word line signal generated by the row controller circuit 118 during the analog in-memory compute operation. The array 112 is segmented into P sub-arrays 113o to 113p-i. Each sub-array 113 includes M columns and N/P rows of memory cells 114.

The memory cells in a common column of each sub-array 113 are connected to each other through a local read bit line RBL. The local read bit lines RBL₀ to RBL_{P-1} in a common column of the matrix across the whole array 112 are each capacitively coupled to a global bit line GBL<x> for that column. Here, x=0 to M−1. The capacitive coupling (identified as C_{C}) may be implemented using a capacitor device or through the parasitic capacitance that exists between two parallel extending closely adjacent metal lines. The global bit lines GBL<0> to GBL<M−1> are coupled to a column processing circuit 120 that senses the analog signals on the global bit lines GBL for the M columns (for example, using a sample and hold circuit), converts the analog signals to digital signals (for example, using an analog-to-digital converter circuit), performs digital signal processing calculations on the digital signals (for example, using a digital signal processing circuit) and generates a decision output for the in-memory compute operation. For the in-memory compute operation, a plurality of read word lines RWL (limited to only one read word line RWL per sub-array 113) are simultaneously asserted by the row decoder circuit 118 with word line signals. The word line signals applied to the read word lines, and driven by the word line driver circuits 116b, are generated from feature data input to the in-memory computation circuit 110.

The row controller circuit 118 receives the feature data for the in-memory compute operation and in response thereto performs the function of selecting which ones of the read word lines RWL<0> to RWL<N−1> are to be simultaneously accessed (or actuated) in parallel during an analog in-memory compute operation, and further functions to control application of pulsed signals to the word lines in accordance with that in-memory compute operation. FIG. illustrates, by way of example only, the simultaneous actuation of the first read word line in each sub-array 113 with the pulsed word line signals. The signal on each local read bit line RBL during the memory compute operation is dependent on the logic state of the bit of the computational weight stored in the memory cell 114 of the corresponding column and the logic state of the pulsed read word line signal applied to the memory cell 114. The logical computation processing operation performed by circuitry within each memory cell 114 is effectively a form of logically NANDing the stored weight bit and the feature data bit, with the logic state of the NAND output provided on the local read bit line RBL. The voltage on the local read bit line RBL will remain at the bit line precharge voltage level (i.e., logic high—Vpch1) if either or both the stored weight bit (at the complementary storage node QC) and the feature data bit (word line signal) are logic low, and there is no impact on the global bit line voltage level. However, the voltage on the local read bit line RBL will discharge from the bit line precharge voltage level to ground (i.e., logic low—Gnd) if both the stored weight bit (at the complementary storage node QC) and the feature data bit (word line signal) are logic high, and due to capacitive coupling and charge sharing this causes a −ΔV swing in the global bit line voltage from the global bit line precharge voltage level (Vpch2). The following table illustrates the truth table for memory cell 114 operation:

| Weight data | Feature data | | |
|---|---|---|---|
| bit - QC | bit - WL | RBL | GBL |
| 0 | 0 | Vpch1 | Vpch2 |
| 0 | 1 | Vpch1 | Vpch2 |
| 1 | 0 | Vpch1 | Vpch2 |
| 1 | 1 | Gnd | Charge transfer with −ΔV swing |

FIG. 6 is a timing diagram showing simultaneous application of word line signals dependent on the feature data to one row of memory cells 114 in each sub-array 113 of the array 112 for a given analog in-memory compute operation. In this particular example, each sub-array 113 includes two rows of memory cells and the first read word lines (RWL<0>, RWL<2>, . . . , RWL<N−2>) of each sub-array 113 are being simultaneously driven by pulsed word line signals conveying the feature data for the in-memory compute operation. Each pulsed word line signal when asserted has a same pulse width. The timing diagram of FIG. 6 further shows the signals on each local read bit line RBL dependent on the logic state of the bits of the computational weight stored in the memory cells 114. In this example, the memory cells 114 in sub-arrays 1130 and 113P-1 accessed by the word line signal pulses on read word lines RWL<0> and RWL<N−2> each store a logic high value at the complement data storage node QC, and so the local read bit lines RBL₀ and RBL_{P-1} will discharge from the precharge voltage level (Vpch1) to ground (logic low). Conversely, the memory cell 114 in sub-array 1131 accessed by the word line signal pulse on read word line RWL<2> stores a logic low value at the complement data storage node QC, and so the local read bit line RBL₁ will not discharge and remain at the precharge level (Vpch1; logic high). Due to capacitive coupling, there is charge sharing between each of the local read bit lines RBL₀, . . . , RBL_{P-1} and the global bit line GBL. As result, the voltage on the global bit line GBL will change from the precharge level to a global bit line voltage level Va,GBL that is dependent on the number K of the P local read bit lines RBL that were discharged to ground (logic low). More specifically, each local read bit line RBL discharged to ground contributes a change (decrease of voltage ΔV) in the voltage on the global bit line GBL. Thus, the global bit line voltage level Va,GBL will decrease from the precharge voltage level (Vpch2) by K*ΔV. The change in voltage ΔV contributed by each of the K discharged local read bit lines RBL is equal to (C_{C}/C_{GBL})Vpch1, where C_{C} is the coupling capacitance and C_{GBL} is the global bit line capacitance. The representation of the voltage level Va,GBL (which is equal to Vpch2−K*ΔV) as shown is just an example. Within the time of the computation cycle of the analog in-memory compute operation, the analog-to-digital converter (ADC) circuit of the column processing circuit 120 will sample (at time ts) the voltage Va,GBL level for analog-digital conversion to a digital signal which is then subjected to the required digital signal processing computations for generating the decision output. After completion of the computation cycle, the local read bit line RBL voltage levels and the global bit line GBL voltage level return to the bit line precharge level.

In a possible implementation where N/P=2, there are two rows per sub-array 113. While the examples of FIGS. 5 and 6 show an implementation where each sub-array 113 includes two rows of memory cells, it will be understood that the N/P rows of memory cells 114 in each sub-array 113 can be any selected integer value, including a value as low as one and as high as selected based on an evaluation of system tradeoff. Selection of the ratio N/P can be made in accordance with setting a row parallelism figure to achieve a desired in-memory computation processing throughput. Furthermore, although the examples of FIGS. 5 and 6 show an implementation where the feature data causes the corresponding read word lines of each sub-array 113 to be simultaneously driven by pulsed word line signals, it will be understood that the decoding of the feature data by the row controller circuit 118 can result in the selection any one word line per sub-array 113 (and further can result in the selection of no word line in a given sub-array).

With reference once again to FIG. 3, the implementation of the 8T SRAM memory cell 114 in the array 112 shows the complement data storage node QC coupled to the gate of the transistor 38 with the read word line RWL coupled to the gate of the transistor 40. In an alternative implementation, the complement data storage node QC could instead be coupled to the gate of the transistor 40 with the read word line RWL coupled to the gate of the transistor 38 (see, for example, FIG. 18). This alternative implementation may be preferred in some embodiments as it presents improved noise performance.

Additionally, FIG. 3 illustrates the precharge circuitry used for pre-charging the local read bit line RBL to a first precharge voltage level Vpch1 (for example, Vdd) and for pre-charging the global bit line GBL to a second precharge voltage level Vpch2 (for example, Vdd). In an example of this precharge circuitry, a p-channel MOS transistor P1 has its source node connected to the first precharge voltage level Vpch1 node and its drain node connected to the read bit line RBL. A gate of the transistor P1 is driven by precharge control signal LPCH. Additionally, a p-channel MOS transistor P2 has its source node connected to the second precharge voltage level Vpch2 node and its drain node connected to the global bit line GBL. A gate of the transistor P2 is driven by precharge control signal GPCH. The read bit line RBL is capacitively coupled (C_{C}) to the global bit line GBL.

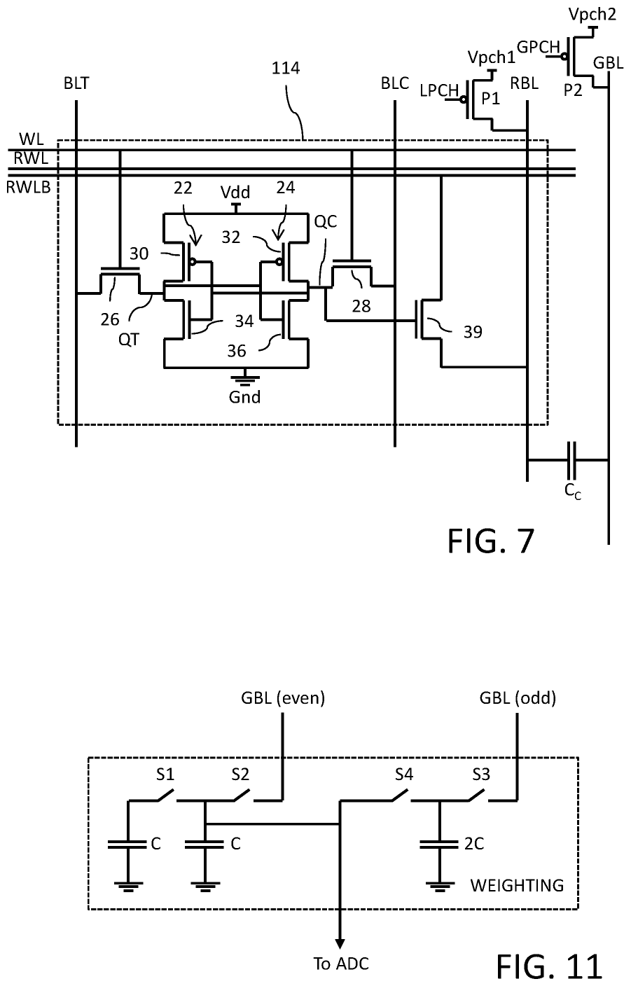

Reference is now made to FIG. 7 which shows an alternative embodiment for the memory cell 114 for use in the circuit 110. The cell 114 includes two cross-coupled CMOS inverters 22 and 24, each inverter including a series connected p-channel and n-channel MOSFET transistor pair. The inputs and outputs of the inverters 22 and 24 are coupled to form a latch circuit having a true data storage node QT and a complement data storage node QC which store complementary logic states of the stored data bit. The cell 114 further includes two transfer (passgate) transistors 26 and 28 whose gate terminals are driven by a word line WL. The source-drain path of transistor 26 is connected between the true data storage node QT and a node associated with a true bit line BLT. The source-drain path of transistor 28 is connected between the complement data storage node QC and a node associated with a complement bit line BLC. The source terminals of the p-channel transistors 30 and 32 in each inverter 22 and 24 are coupled to receive a high supply voltage (for example, Vdd) at a high supply node, while the source terminals of the n-channel transistors 34 and 36 in each inverter 22 and 24 are coupled to receive a low supply voltage (for example, ground (Gnd) reference) at a low supply node. A signal path between the read bit line RBL and a logical inverse RWLB of the read word line RWL is formed by the source-drain path of transistor 39. The gate terminal of the transistor 39 is coupled to the complement storage node QC. In this embodiment, when the read word line signal pulses logic high (and thus the logical inverse RWLB pulses logic low), the read bit line RBL will discharge to ground (logic low) if the weight bit stored on the complement data storage node QC is logic high to turn on transistor 39. Otherwise, such as if either or both the feature data bit and the weight bit are logic low, the voltage on the read bit line RBL will remain at the precharge voltage level. Thus, this implementation of the memory cell also supports logically NANDing the stored weight bit (at the QC node) and the feature data bit (provided by the word line signal).

With reference once again to FIG. 5, a control circuit 119 controls mode switching operations of the circuitry within the circuit 110 responsive to the logic state of a control signal IMC. When the control signal IMC is in a first logic state (for example, logic low), the circuit 110 operates in accordance with the conventional memory access mode of operation (for writing data from data input port D to the memory array or reading data from the memory array to data output port Q). Conversely, when the control signal IMC is in a second logic state (for example, logic high), the circuit 110 operates in accordance with the analog in-memory compute mode of operation (for logically NANDing weight and feature data bits and generating the global bit line voltage level Va,GBL outputs for analog-to-digital signal conversion and digital signal processing).

When the circuit 110 is operating in the conventional memory access mode of operation, the row decoder circuit 118 decodes an address, and selectively actuates only one word line WL (during read or write) for the whole array 112 with a word line signal pulse to access a corresponding single one of the rows of memory cells 114. In a write operation, logic states of the data at the input ports D are written by the column I/O circuits 120 through the pairs of complementary bit lines BLT, BLC to the memory cells at the word line WL accessed single one of the rows. In a read operation, the logic states of the data stored in the memory cells at the word line WL accessed single one of the rows are output from the pairs of complementary bit lines BLT, BLC to the column I/O circuits for output at the data output ports Q.

When the circuit 110 is operating in the in-memory compute mode of operation, the row decoder circuit 118 decodes an address associated with the feature data, and selectively (and simultaneously) actuates one read word line RWL in each sub-array 113 in the memory array 112 with a word line signal pulse to access a corresponding single one of the rows of memory cells 114 in each sub-array 113. The logic states of the weight data stored in the memory cells at the accessed single one of the rows in each sub-array 113 are then logically NANDed with the logic state of the read word line signal to produce an output on the local read bit line RBL.

The following table illustrates the full address decoding function performed by the control circuit 119 and row decoder 118 for the circuit 110 shown in FIG. 5 for an example implementation where P=4 and N=32. Thus, each sub-array 113 includes N/P=8 rows. There would be five bits in the address Addr<A0,A1,A2,A3,A4> needed to individually address the 32 rows. The left side of the table shows the logic states for the possible addresses, the middle of the table shows the actuated word line WL for each address when the control signal IMC is in the first logic state (for example, logic low—when the circuit 110 is operating in accordance with the conventional memory access mode of operation), and the right side of the table shows the actuated word lines RWL for each address when the control signal IMC is in the second logic state (for example, logic high—when the circuit 110 is operating in accordance with the in-memory compute mode of operation). In the case of the in-memory compute mode of operation, the address input for decoding to make word line selections would come from the feature data FD bus as opposed to the address bus in response to the control signal IMC being in the second logic state.

| A4 | A3 | A2 | A1 | A0 | Conv. Mode | IMC Mode | | | |
|---|---|---|---|---|---|---|---|---|---|
| 0 | 0 | 0 | 0 | 0 | WL<0> | RWL<0> | RWL<8> | RWL<16> | RWL<24> |
| 0 | 0 | 0 | 0 | 1 | WL<1> | RWL<1> | RWL<9> | RWL<17> | RWL<25> |
| 0 | 0 | 0 | 1 | 0 | WL<2> | RWL<2> | RWL<10> | RWL<18> | RWL<26> |
| 0 | 0 | 0 | 1 | 1 | WL<3> | RWL<3> | RWL<11> | RWL<19> | RWL<27> |
| 0 | 0 | 1 | 0 | 0 | WL<4> | RWL<4> | RWL<12> | RWL<20> | RWL<28> |
| 0 | 0 | 1 | 0 | 1 | WL<5> | RWL<5> | RWL<13> | RWL<21> | RWL<29> |
| 0 | 0 | 1 | 1 | 0 | WL<6> | RWL<6> | RWL<14> | RWL<22> | RWL<30> |
| 0 | 0 | 1 | 1 | 1 | WL<7> | RWL<7> | RWL<15> | RWL<23> | RWL<31> |
| 0 | 1 | 0 | 0 | 0 | WL<8> | RWL<0> | RWL<8> | RWL<16> | RWL<24> |
| 0 | 1 | 0 | 0 | 1 | WL<9> | RWL<1> | RWL<9> | RWL<17> | RWL<25> |
| 0 | 1 | 0 | 1 | 0 | WL<10> | RWL<2> | RWL<10> | RWL<18> | RWL<26> |
| 0 | 1 | 0 | 1 | 1 | WL<11> | RWL<3> | RWL<11> | RWL<19> | RWL<27> |
| 0 | 1 | 1 | 0 | 0 | WL<12> | RWL<4> | RWL<12> | RWL<20> | RWL<28> |
| 0 | 1 | 1 | 0 | 1 | WL<13> | RWL<5> | RWL<13> | RWL<21> | RWL<29> |
| 0 | 1 | 1 | 1 | 0 | WL<14> | RWL<6> | RWL<14> | RWL<22> | RWL<30> |
| 0 | 1 | 1 | 1 | 1 | WL<15> | RWL<7> | RWL<15> | RWL<23> | RWL<31> |
| 1 | 0 | 0 | 0 | 0 | WL<16> | RWL<0> | RWL<8> | RWL<16> | RWL<24> |
| 1 | 0 | 0 | 0 | 1 | WL<17> | RWL<1> | RWL<9> | RWL<17> | RWL<25> |
| 1 | 0 | 0 | 1 | 0 | WL<18> | RWL<2> | RWL<10> | RWL<18> | RWL<26> |
| 1 | 0 | 0 | 1 | 1 | WL<19> | RWL<3> | RWL<11> | RWL<19> | RWL<27> |
| 1 | 0 | 1 | 0 | 0 | WL<20> | RWL<4> | RWL<12> | RWL<20> | RWL<28> |
| 1 | 0 | 1 | 0 | 1 | WL<21> | RWL<5> | RWL<13> | RWL<21> | RWL<29> |
| 1 | 0 | 1 | 1 | 0 | WL<22> | RWL<6> | RWL<14> | RWL<22> | RWL<30> |
| 1 | 0 | 1 | 1 | 1 | WL<23> | RWL<7> | RWL<15> | RWL<23> | RWL<31> |
| 1 | 1 | 0 | 0 | 0 | WL<24> | RWL<0> | RWL<8> | RWL<16> | RWL<24> |
| 1 | 1 | 0 | 0 | 1 | WL<25> | RWL<1> | RWL<9> | RWL<17> | RWL<25> |
| 1 | 1 | 0 | 1 | 0 | WL<26> | RWL<2> | RWL<10> | RWL<18> | RWL<26> |
| 1 | 1 | 0 | 1 | 1 | WL<27> | RWL<3> | RWL<11> | RWL<19> | RWL<27> |
| 1 | 1 | 1 | 0 | 0 | WL<28> | RWL<4> | RWL<12> | RWL<20> | RWL<28> |
| 1 | 1 | 1 | 0 | 1 | WL<29> | RWL<5> | RWL<13> | RWL<21> | RWL<29> |
| 1 | 1 | 1 | 1 | 0 | WL<30> | RWL<6> | RWL<14> | RWL<22> | RWL<30> |
| 1 | 1 | 1 | 1 | 1 | WL<31> | RWL<7> | RWL<15> | RWL<23> | RWL<31> |

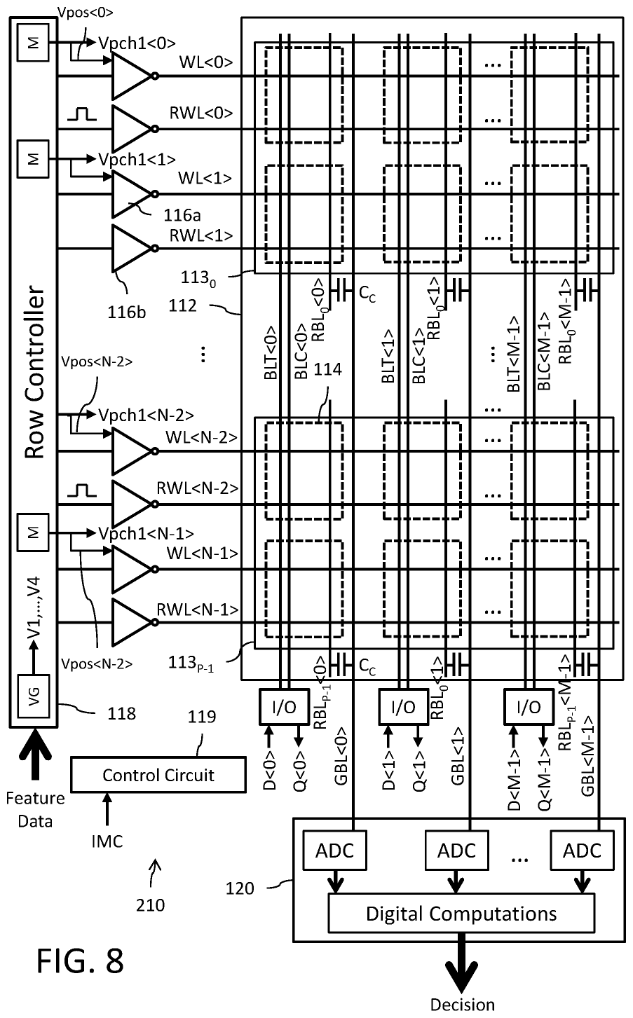

Reference is now made to FIG. 8 which shows a block diagram of an analog in-memory computation circuit 210. Like references in FIGS. 5 and 8 refer to same or similar components. The primary difference between the circuit 210 of FIG. 8 and the circuit 110 of FIG. 5 concerns the number of bits for the feature data. In FIG. 5, the feature data being processed is single bit feature data (i.e., the feature data applied to each selected row in a given one of the sub-arrays 113 is single bit data (logic 1 or logic 0) dependent on the word line signal). In the implementation of FIG. 8, however, the circuit 210 supports multi-bit feature data (i.e., the feature data applied to each selected row in a given one of the sub-arrays 113 is 10 multi-bit data (such as 2-bit feature data including logic 00, logic 01, logic 10 or logic 11)). This 2-bit feature data is not presented through the logic high/low state of the word line signal. Instead, in this embodiment, the multi-bit feature data is used to control a modulation of the first precharge voltage level Vpch1 for the local read bit lines RBL. With two bits of feature data, there are four possible voltages for the first precharge voltage level Vpch1 as illustrated by the following table:

| | |
|---|---|
| Feature data bits | Vpch1 |

| | | |
|---|---|---|
| 0 | 0 | V1 = 0.0 V |
| 0 | 1 | V2 = 0.3 V |
| 1 | 0 | V3 = 0.6 V |
| 1 | 1 | V4 = 1.2 V |

As previously noted, the change in voltage ΔV contributed by each of the K discharged local read bit lines RBL is equal to (C_{C}/C_{GBL})Vpch1, where Vpch1 is one of the voltages V1, . . . , V4 as selected by the feature data.

The row controller circuit 118 may, for example, include voltage generator (VG) circuits for generating the voltages V1, . . . , V4 and analog multiplexing (M) circuits coupled to receive the voltages and controlled by the received feature data for selecting one of the generated voltages for output as the first precharge voltage level Vpch1<z> for each row. Here, z=0 to N−1. Alternatively, a first precharge voltage level Vpch1<y> is generated for each sub-array. Here, y=0 to P−1.

In a preferred embodiment, the second precharge voltage level Vpch2 is fixed, and the level of the second precharge voltage level Vpch2 is set to conform to the dynamic range of the analog-to-digital converter circuit. For example, Vpch2=Vdd.

With reference once again to FIG. 3, the transistor P1 may, in the case of this multi-bit feature data embodiment, instead be implemented as a transmission gate circuit (i.e., parallel connected n-channel and p-channel transistors gate controlled by logical inverses of the precharge control signal LPCH) in order to ensure that the full level of the voltages V1, . . . , V4 is provided to the source node of transistor P1.

With reference once again to FIG. 7, an alternative way of supporting multi-bit feature data is supported in connection with the generation and assertion of the word line signal on the logical inverse RWLB of the read word line RWL. In this case, the multi-bit feature data controls a modulation of the positive voltage level of the word line signal pulse on the logical inverse RWLB. The transistor 39 may be implemented as a transmission gate in order to support transfer of a full range of Vdd. With two bits of feature data, there are four possible voltages for the word line signal pulse positive voltage level (Vpos) as illustrated by the following table:

| | |
|---|---|
| Feature data bits | WL Vpos |

| | | |
|---|---|---|
| 0 | 0 | V1 = 0.0 V |
| 0 | 1 | V2 = 0.3 V |
| 1 | 0 | V3 = 0.6 V |
| 1 | 1 | V4 = 1.2 V |

This can be accomplished, for example, by modulating the supply voltage for the word line driver circuits 116b. The row controller circuit 118 may, for example, include voltage generator (VG) circuits for generating the voltages V1, . . . , V4 and analog multiplexing (M) circuits configured to receive the voltages and controlled by the received feature data for selecting one of the generated voltages for output as the word line driver positive supply voltage Vpos<z> for the driver circuit 116b of each row. Here, z=0 to N−1. Alternatively, a word line driver positive supply voltage Vpos<y> is generated for the driver circuits 116b of each sub-array. Here, y=0 to P−1. It will be noted that in this implementation, the precharge voltage Vpch1 at the source of transistor P1 is fixed (for example, equal to Vdd).

In this case, the change in voltage ΔV contributed by each of the K discharged local read bit lines RBL is equal to (C_{C}/C_{GBL})Vpos, where Vpos is one of the voltages V1, . . . , V4 as selected by the feature data.

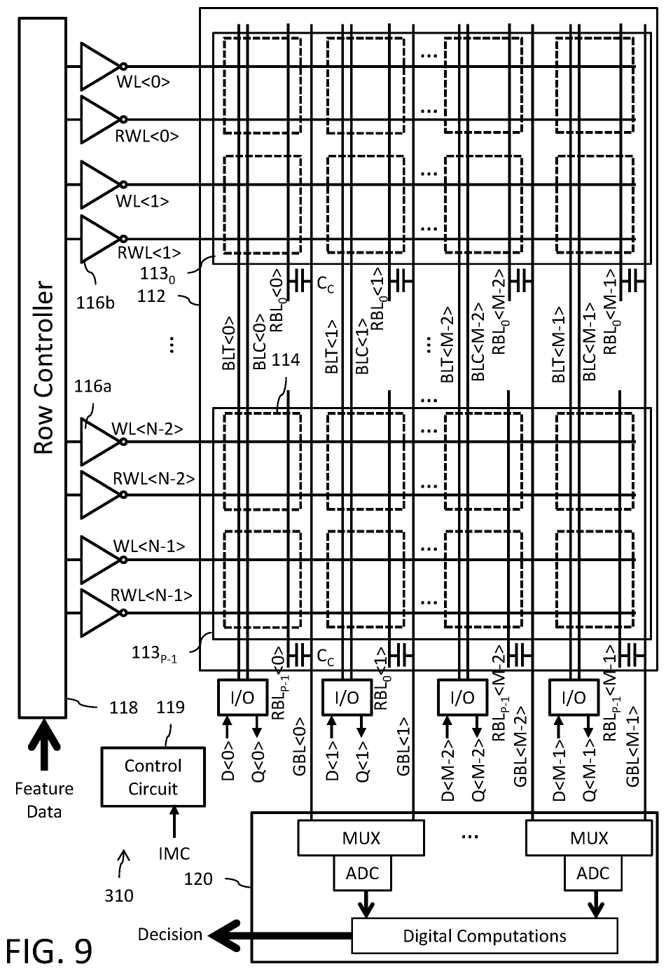

Reference is now made to FIG. 9 which shows a block diagram of an analog in-memory computation circuit 310. Like references in FIGS. 5 and 9 refer to same or similar components. The primary difference between the circuit 310 of FIG. 9 and the circuit 110 of FIG. 5 concerns the number of bits for the weight data. In FIG. 5, the weight data being processed is single bit weight data (i.e., the weight data stored in each of the columns of the array 112 is single bit data (logic 1 or logic 0)). In the implementation of FIG. 9, however, the circuit 310 supports multi-bit weight data (i.e., the weight data stored in cells 114 of multiple columns is multi-bit data (such as 2-bit weight data including logic 00, logic 01, logic 10 or logic 11) stored in a pair of cells 114 associated with a pair of columns). Although FIG. 9 shows the pair of memory cells 114 and associated pair of columns as being immediately adjacent to each other, this is by example only and it will be understood that immediately adjacent positioning of structures supporting multi-bit weight data is not required, and indeed in some cases (such as where radiation upset of the stored data bits is a concern) is not recommended.

In support of the use of multi-bit weight data, the column processing circuit 120 includes a multiplexing circuit MUX for each pair of columns that is coupled to the corresponding pair of global bit lines GBL. The memory cells 114 in one column of the pair of columns (for example, the even numbered column) store the least significant bits of the multi-bit weight data, while the memory cells 114 in the other column of the pair of columns (for example, the odd numbered column) store the most significant bits of the multi-bit weight data. The multiplexing circuit MUX selectively couples the global bit line voltage Va,GBL from the global bit line GBL for the even column to the analog-to-digital converter circuit for conversion of the analog voltage to a first digital value. This first digital value is then stored by the digital signal processing circuit. The multiplexing circuit MUX then selectively couples the global bit line voltage Va,GBL from the global bit line GBL for the odd column to the analog-to-digital converter circuit for conversion of the analog voltage to a second digital value. The second digital value is then processed with the previously stored first digital value using an add and shift operation to generate a combined digital value. The digital signal processing circuit can then perform further digital calculations on the combined digital values from all pairs of columns to generate a decision output for the in-memory compute operation.

Although the implementation of FIG. 9 shows a MUX-ing of the pair of global bit lines GBL to a shared ADC circuit, it will be understood that this is by example only and that in an alternative implementation an ADC circuit could be provided for each column (see, FIGS. 5 and 8, for example) and the data on the global bit lines would be parallelly processed.

It will be understood that the implementations of FIGS. 8 and 9 can be combined in order to support both multi-bit feature data and multi-bit weight data. Thus, the row controller 118 in such an embodiment would be implemented as shown in FIG. 8 and the processing circuit 120 would be implemented as shown in FIG. 9.

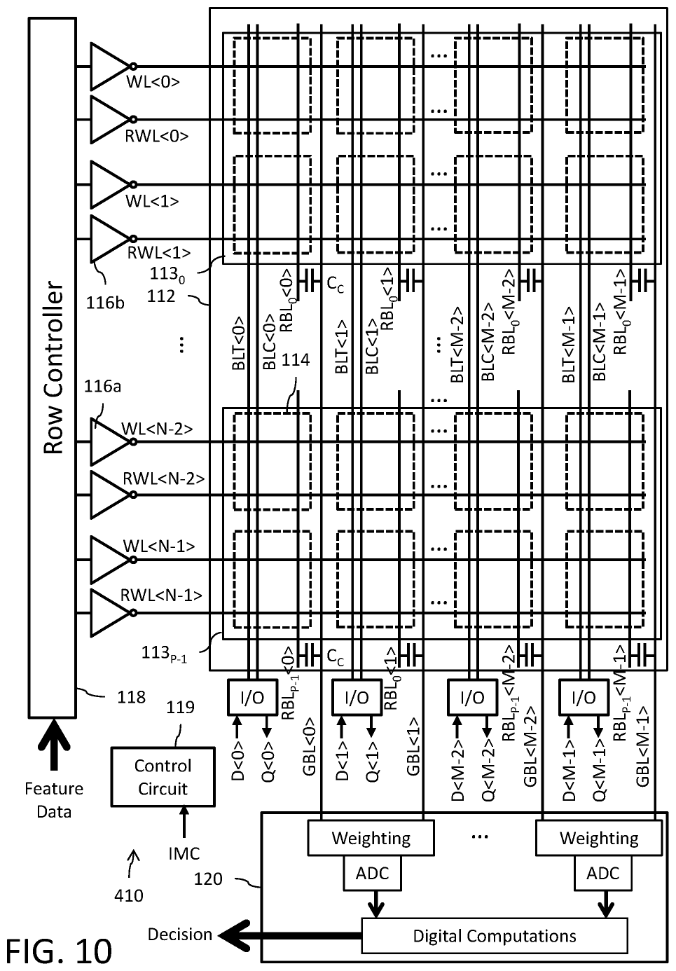

Reference is now made to FIG. 10 which shows a block diagram of an analog in-memory computation circuit 410. Like references in FIGS. 5 and 10 refer to same or similar components. The primary difference between the circuit 410 of FIG. 10 and the circuit 110 of FIG. 5 concerns the number of bits for the weight data. In FIG. 5, the weight data being processed is single bit weight data (i.e., the weight data stored in the columns of the array 112 is single bit data (logic 1 or logic 0)). In the implementation of FIG. 10, however, the circuit 410 supports multi-bit weight data (i.e., the weight data stored in cells 114 of multiple columns is multi-bit data (such as 2-bit weight data including logic 00, logic 01, logic 10 or logic 11) stored in a pair of cells 114 associated with a pair of columns).

In support of the use of multi-bit weight data, the column processing circuit 120 includes a weighting circuit for each pair of columns that is coupled to the corresponding pair of global bit lines GBL. The memory cells 114 in one column of the pair of columns (for example, the even numbered column) store the least significant bits (LSBs) of the multi-bit weight data, while the memory cells 114 in the other column of the pair of columns (for example, the odd numbered column) store the most significant bits (MSBs) of the multi-bit weight data. The weighting circuit implements a switched capacitor function (see, FIG. 11) to selectively charge share between the global bit line GBL for the even column and two first capacitors of equal capacitance C and selectively charge share between the global bit line GBL for the odd column and one second capacitor of double the capacitance 2C of each of the first capacitors (FIG. 11, switches S1, S2, S3 closed, switch S4 open). Then, the switched capacitor function permits charge sharing between one of the first capacitors and the second capacitor (FIG. 11, switches S1, S2, S3 open, switch S4 closed) with the signal contribution from the odd column (for the MSB) being more heavily weighted than the signal contribution from the even column (for the LSB) due to the difference in capacitance. The analog voltage which develops on those charge sharing capacitors is converted by the analog-to-digital converter circuit to a digital value and the digital signal processing circuit performs digital calculations on the digital values from all pairs of columns to generate a decision output for the in-memory compute operation.

It will be understood that the implementations of FIGS. 8 and 10 can be combined in order to support both multi-bit feature data and multi-bit weight data. Thus, the row controller 118 in such an embodiment would be implemented as shown in FIG. 8 and the processing circuit 120 would be implemented as shown in FIG. 10.

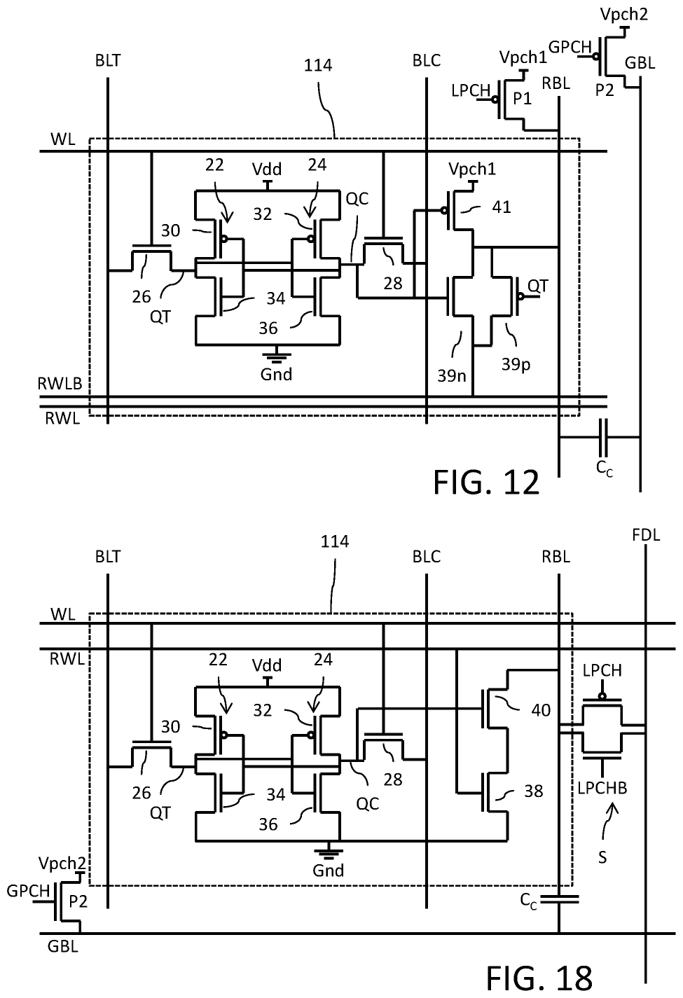

FIG. 12 illustrates an alternative embodiment for the memory cell 114. Like references in FIGS. 7 and 12 refer to same or similar components. In the FIG. 12 embodiment, a signal path between the read bit line RBL and a logical inverse RWLB of the read word line RWL is formed by a transmission gate comprising parallel connected n-channel transistor 39n and p-channel transistor 39p. The gates of transistors 39n and 39p are coupled to the storage nodes QC and QT, respectively. Furthermore, the read bit line RBL is coupled to the precharge voltage Vpch1 supply node through the source-drain path of transistor 41. The gate terminal of the transistor 39 is coupled to the complement storage node QC. This embodiment may be used in connection with the multi-bit feature data implementation where the positive voltage level of the pulse on the logical inverse RWLB for the word line signal is modulated by the feature data bits. It will be noted that in this implementation, the precharge voltage Vpch2 is fixed (for example, equal to Vdd).

It will be noted that the precharge transistor P1 is redundant of transistor 41 and can be omitted if desired. In other words, the presence of transistor P1 in this implementation is optional.

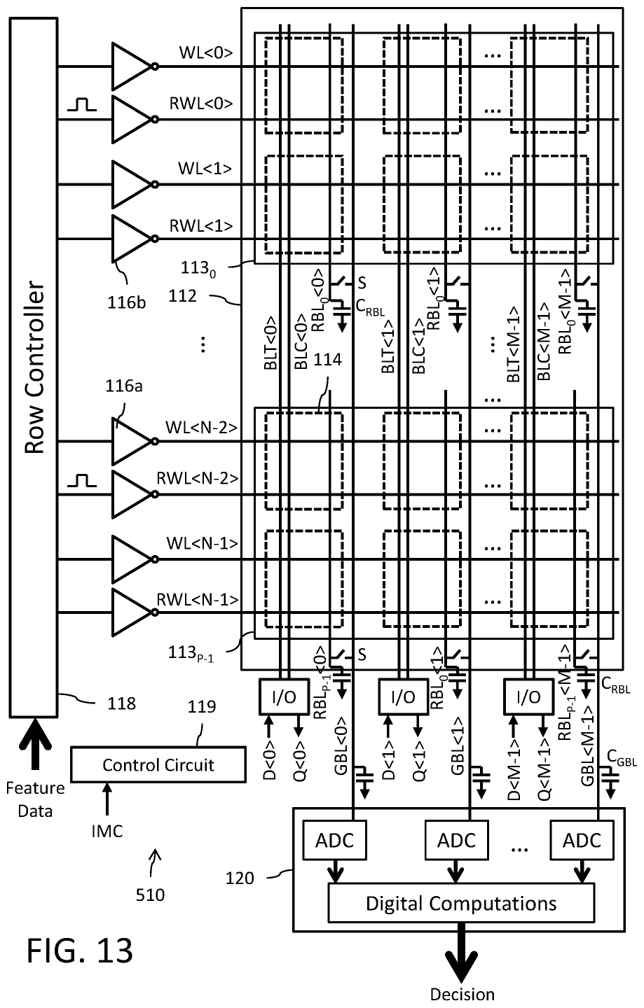

Reference is now made to FIG. 13 which shows a block diagram of an analog in-memory computation circuit 510. Like references in FIGS. 5 and 13 refer to same or similar components. The primary difference between the circuit 510 of FIG. 13 and the circuit 110 of FIG. 5 concerns how the local read bit lines RBL in a column are coupled to the global bit line GBL for that column. In the implementation of FIG. 5, there is a capacitive coupling between each local read bit line RBL and the global bit line GBL for supporting charge sharing. In the implementation of FIG. 13, however, there is a switched coupling between capacitances of each local read bit line RBL and the capacitance of the global bit line GBL to support charge sharing. A switch S selectively electrically connects the local read bit line RBL to the global bit line GBL. The switch S may, for example, be implemented by a transmission gate comprising parallel connected n-channel and p-channel transistors gate controlled by logical inverses of a switch control signal. In an embodiment, the switch control signal may be provided by the logical inverse of the precharge control signal GPCH, or a signal derived from the timing of the precharge control signals LPCH or GPCH. For example, the switch S may be controlled to be open during precharge of the read bit lines RBL to the precharge voltage Vpch1, and closed when (or for a period of time after) precharge is disabled and the in-memory compute operation is being performed. In a separate implementation, it will be noted that the precharge of the global bit line GBL can support precharge of the read bit line RBL through the actuation of the switch S during the precharge cycle. The switch S will be controlled to be open during the NAND-ing operation in the bit cell, and then closed during the accumulation (charge sharing) phase. Each read bit line RBL has an associated capacitance C_{RBL} (where the capacitance C_{RBL} may be provided by the inherent metal line capacitance of the bit line itself and/or supplemented by an actual capacitor structure). Each global bit line GBL has an associated capacitance C_{GBL} (where the capacitance C_{GBL} may be provided by the inherent metal line capacitance of the bit line itself and/or supplemented by an actual capacitor structure). When the switch S is selectively closed, there will be a charge sharing between the capacitance of each local read bit line RBL and the capacitance of the global bit line GBL. As previously noted, there will be a change in voltage ΔV on the global bit line GBL contributed by each of the K discharged local read bit lines RBL. This change in voltage is equal to ((C_{GBLtot}−K*C_{RBL})/C_{GBLtot})*Vpch1, where C_{GBLtot}=C_{GBL} N*C_{RBL}, N equal to the number of rows in the array 112.

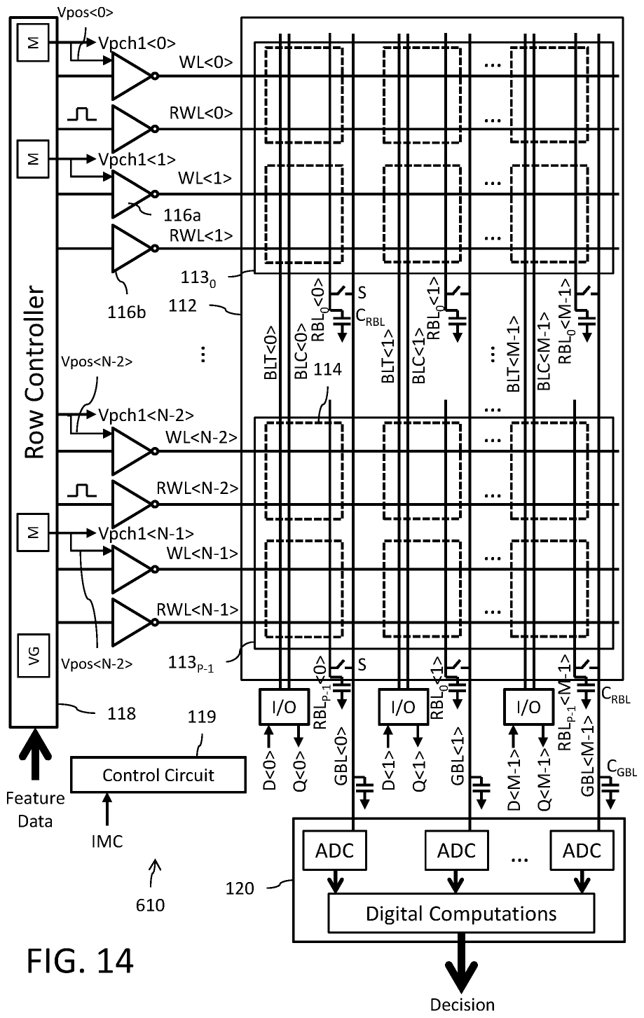

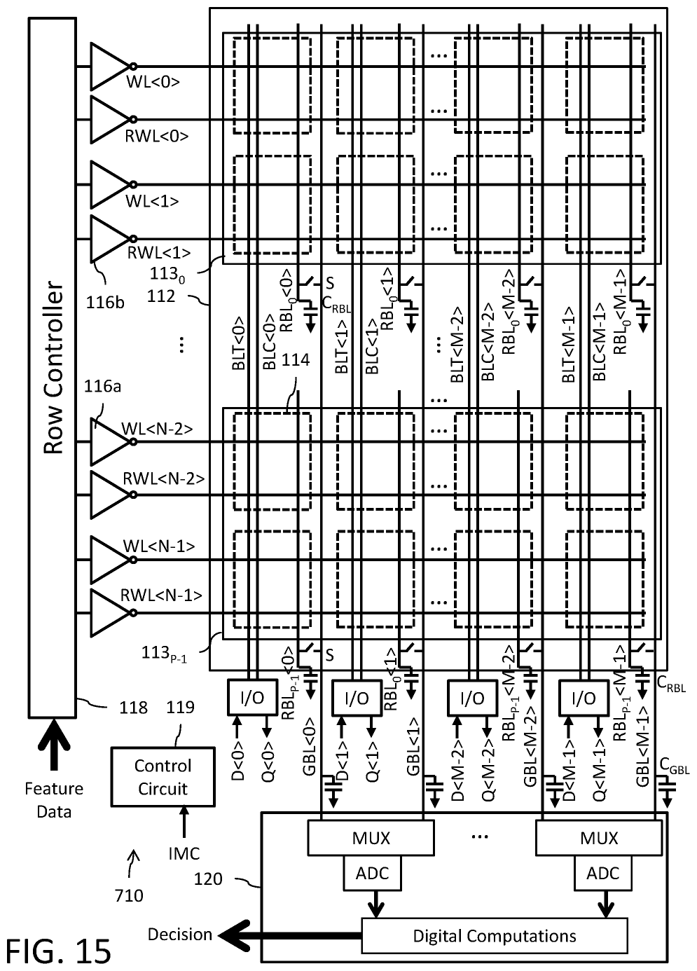

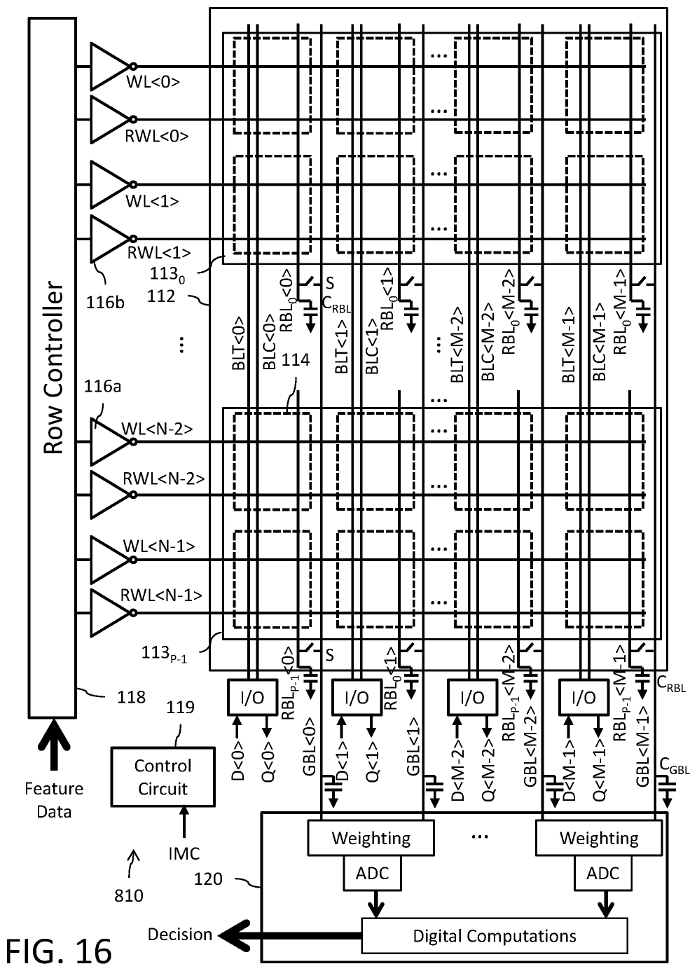

The implementation of switched coupling between each local read bit line RBL and the global bit line GBL as shown in FIG. 13 can also be provided in substitution for the capacitive coupling used in the analog in-memory computation circuit shown in FIG. 8 (see circuit 610 in FIG. 14), or the analog in-memory computation circuit shown in FIG. 9 (see circuit 710 in FIG. 15), or the analog in-memory computation circuit shown in FIG. 10 (see circuit 810 in FIG. 16).

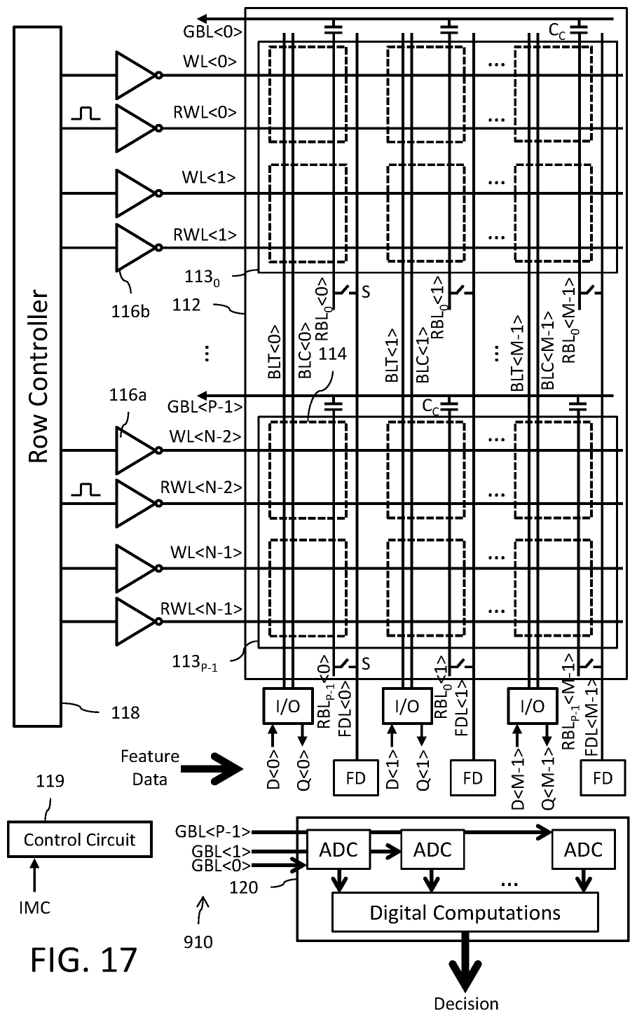

For the implementations of the analog in-memory computation circuit shown in FIGS. 5, 8-10 and 13-16, the global bit line GBL extends parallel to each column of memory cells 114 and is coupled (capacitively or switched) to the read bit lines RBL of that column, with the feature data applied by the row controller circuit 118 to a selected one of the rows of memory cells 114 in each sub-array 113. FIGS. 17 and 18 illustrate an alternative implementation for the analog in-memory computation circuit 910 where the global bit line GBL extends parallel to each sub-array 113 and is capacitively coupled (reference C_{C}) to each of the read bit lines RBL for the columns of that sub-array, with the feature data applied through feature data lines FDL<0> to FDL<M−1> which extend parallel to each column of memory cells 114 of the array 112 and are switch coupled (reference S) to the read bit lines RBL of the column.

The bits of the feature data for the in-memory compute operation are latched by feature data registers (FD) coupled to apply the feature data bits to corresponding feature data lines FDL<0> to FD<M−1>. The precharge control signal GPCH is asserted to precharge the global bit lines GBL to the precharge voltage Vpch2. The precharge control signal LPCH is also asserted to turn on the switches S and precharge the local read bit lines RBL₀<x> to RBL_{P-1}<x> to the voltage level of the logic state of the feature data bit stored in the feature data register FD and applied to the feature data line FDL<x>. Here, x=0 to P−1 (it will be noted that here P−1 is M−1, but the feature data FDL is individually available for the P sub-arrays, and thus FDL<y><x> is also possible for one column where y=0 to P−1). When the precharge control signals LPCH and GPCH are then deasserted, the switches S are opened and the in-memory compute operation can begin. One word line per sub-array 113 is then asserted by the row controller circuit 118 to turn on transistor 38 and the logic state of the weight bit at the complement storage node QC controls the on/off state of the transistor 40. The signal on each local read bit line RBL during the memory compute operation is dependent on the logic state of the bit of the computational weight stored in the memory cell 114 of the corresponding column and the logic state of the feature data bit used to precharge the local read bit line RBL. The processing operation performed within each memory cell 114 is effectively a form of logically NANDing the stored weight bit and the feature data bit (from the feature data line FDL), with the logic state of the NAND output provided on the local read bit line RBL. The voltage on the local read bit line RBL will show a voltage swing from logic high to logic low when both the feature data and the stored weight bit are logic high. Due to capacitive coupling and charge sharing, there will be a change in the global bit line voltage on the global bit line GBL from the global bit line precharge voltage level (Vpch2).

The embodiments of the analog in-memory computation circuit described herein provide a number of advantages including: the arrangement of the array 112 into sub-arrays 113 with a single word line access per sub-array during in-memory computation addresses and avoids concerns with inadvertent bit flip; the computation operation utilizes charge sharing (either through capacitive coupled or switched coupling) and as a result there is a limited variation in analog signal output levels with a linear response that serves to increase the precision of output sensing; a significant increase in row parallelism is enabled with a minimal impact on occupied circuit area; and increased row parallelism also increases throughput while managing large geometry neural network layer operations.

The foregoing description has provided by way of exemplary and non-limiting examples a full and informative description of the exemplary embodiment of this invention. However, various modifications and adaptations may become apparent to those skilled in the relevant arts in view of the foregoing description, when read in conjunction with the accompanying drawings and the appended claims. However, all such and similar modifications of the teachings of this invention will still fall within the scope of this invention as defined in the appended claims.

1. A circuit, comprising:
a memory array including memory cells arranged in a matrix with plural rows and plural columns, each row including a word line connected to the memory cells of the row, and each memory cell storing a bit of weight data for an in-memory computation operation;
wherein the memory is divided into a plurality of sub-arrays of memory cells, each sub-array including at least one row of said plural rows and said plural columns;
a local bit line for each column of the sub-array;
computation circuitry coupling each memory cell in the column of the sub-array to the local bit line for each column of the sub-array, said computation circuitry configured to logically combine a bit of feature data for the in-memory computation operation with the stored bit of weight data to generate a logical output on the local bit line;
a plurality of global bit lines;
wherein a plurality of local bit lines are coupled for charge sharing to each global bit line;
a word line drive circuit for each row having an output connected to drive the word line of the row;
a row controller circuit coupled to the word line drive circuits and configured to simultaneously actuate one word line per sub-array during said in-memory computation operation; and
a column processing circuit that senses analog signals on the global bit lines generated in response to said charge sharing, converts the analog signals to digital signals, performs digital signal processing calculations on the digital signals and generates a decision output for the in-memory computation operation.

2. The circuit of claim 1, wherein each column of the memory array has an associated global bit line, and wherein the plurality of local bit lines that are coupled for charge sharing with each global bit line comprise local bit lines in a corresponding column of the plurality of sub-arrays.

3. The circuit of claim 2, wherein said feature data is applied to each row of memory cells having an actuated word line.

4. The circuit of claim 3, where a logic state of a word line signal on the actuated word line provides said bit of feature data.

5. The circuit of claim 3, wherein a precharge voltage level on each local bit line in the sub-array provides said bit of feature data.

6. The circuit of claim 3, wherein a voltage level of a word line signal on the actuated word line provides said bit of feature data.

7. The circuit of claim 1, wherein each sub-array has an associated global bit line, and wherein the plurality of local bit lines that are coupled for charge sharing with each global bit line comprise local bit lines in the sub-array.

8. The circuit of claim 7, wherein each column of the memory array has an associated feature data line selectively connected to the local bit lines in corresponding columns of the plurality of sub-arrays, and wherein said feature data is applied to the feature data lines.

9. The circuit of claim 8, further comprising a switch configured to selectively connect each local bit line to the associated feature data line, and wherein said switch is selectively actuated to precharge each local bit line to a voltage level of the bit of feature data.

10. The circuit of claim 1, further comprising a charge sharing circuit coupled between the plurality of local bit lines and each global bit line, said charge sharing circuit comprising a capacitance between each local bit line of said plurality of local bit lines and the global bit line.

11. The circuit of claim 1, further comprising a charge sharing circuit coupled between the plurality of local bit lines and each global bit line, said charge sharing circuit comprising: a first capacitance associated each local bit line of said plurality of local bit lines; a second capacitance associated with the global bit line; and a switch selectively connecting each first capacitance to the second capacitance.

12. The circuit of claim 11, wherein the first capacitance comprises a parasitic capacitance.

13. The circuit of claim 11, wherein the second capacitance comprises a parasitic capacitance.

14. The circuit of claim 11, wherein the first capacitance comprises a device capacitance.

15. The circuit of claim 11, wherein the second capacitance comprises a device capacitance.

16. The circuit of claim 1, further comprising:
a first precharge circuit for each local bit line, said first precharge circuit configured to precharge the local bit line to a first precharge voltage level; and
a second precharge circuit for each global bit line, said second precharge circuit configured to precharge the global bit line to a second precharge voltage level.

17. The circuit of claim 16, wherein said feature data comprises multi-bit feature data, and further comprising a voltage modulation circuit configured to modulate said first precharge voltage level to have a selected one of a plurality voltage levels dependent on the multi-bit feature data.

18. The circuit of claim 17, wherein said selected one of the plurality voltage levels is applied as the first precharge voltage level for all first precharge circuits within a given sub-array.

19. The circuit of claim 17, wherein said selected one of the plurality voltage levels is applied as the first precharge voltage level for all first precharge circuits within a given row of the sub-array.

20. The circuit of claim 1, wherein each word line drive circuit is powered from a positive supply voltage level, and further comprising a voltage modulation circuit configured to modulate said positive supply voltage level to have a selected one of a plurality voltage levels dependent on the multi-bit feature data.

21. The circuit of claim 1, wherein said weight data comprises multi-bit weight data stored in plural memory cells of multiple columns of the memory array, and wherein said column processing circuit is coupled to corresponding multiple global bit lines and configured to process multiple analog signals on the multiple global bit lines.

22. The circuit of claim 21, wherein said column processing circuit comprises a multiplexing circuit configured to sequentially select analog signals from the multiple global bit lines for processing.

23. The circuit of claim 21, wherein said column processing circuit comprises a weighting circuit configured to perform a weighted charge sharing for the analog signal of each one of the multiple global bit lines to produce a weighted signal and then perform a combination charge sharing of the weighted signals.

24. The circuit of claim 1, wherein the memory cells are static random access memory (SRAM) cells.
